(19) United States
(12) Patent Application Publication
(10) Pub. No.: US 2026/0342111 A1
(43) Pub. Date: Oct. 29, 2026

(54) ELECTRONIC CONTROL DEVICE

(71) Applicant: DENSO CORPORATION, Kariya-city (JP)

(72) Inventor: Yutaka YAMANAKA, Kariya-city (JP)

(21) Appl. No.: 19/702,261

(22) Filed: Jun. 9, 2026

Related U.S. Application Data
(63) Continuation of application No. PCT/JP2025/016233, filed on Apr. 28, 2025.

(30) Foreign Application Priority Data
May 30, 2024 (JP) 2024-088007

(51) Int. Cl. H02J 7/60; H02J 7/00; H02J 7/34

(52) U.S. Cl. CPC H02J 7/60; H02J 7/865; H02J 7/345; H02J 2207/50

(57) ABSTRACT

A main element controls current of a wire harness, and current of the main element flows through a sense element. A detection resistor generates a sense voltage corresponding to the current of the sense element. A charge/discharge circuit charges and discharges a capacitor based on the sense voltage. The charge discharge control circuit forcibly switches the charge/discharge circuit to a discharge state if the charging state continues after exceeding an upper limit. An accumulation circuit accumulates a multiplication signal acquired according to the discharge voltage and the subtraction circuit subtracts a subtraction value according to the heat radiation characteristics of the wire harness from the accumulation result. When the subtraction value exceeds an accumulation threshold, the control circuit cuts off the current of the wire harness. When the charge discharge control circuit switches to the discharge state, the accumulation circuit accumulates the acceleration value for cut-off.

### CROSS REFERENCE TO RELATED APPLICATION

The present application is a continuation application of International Patent Application No. PCT/JP 2025/016233 filed on Apr. 28, 2025, which designated the U.S. and claims the benefit of priority from Japanese Patent Application No. 2024-088007 filed on May 30, 2024. The entire disclosures of all of the above applications are incorporated herein by reference.

### TECHNICAL FIELD

This disclosure relates to an electronic control device for protecting a wire harness.

### BACKGROUND

For example, a conceivable technique teaches an electronic control device that protects a wire harness to which a load is connected. This electronic control device is configured to supply power to a load connected to a wire harness via an Intelligent Power Device (IPD) having a main element and a sense element. In the multiplication circuit that calculate the power supplied to the load, the multiplication characteristics are acquired by charging and discharging a capacitor.

The accumulation circuit generates a signal with a pulse width corresponding to the discharge time of the capacitor, and then accumulates the counted values of these pulse widths. If the result of subtracting a value corresponding to the heat radiation characteristics of the wire harness from the accumulated value exceeds a threshold, the power supply to the load via the IPD is cut off to protect the wire harness. In the following, this type of wire harness protection mechanism may be referred to as “e-Fuse”.

### SUMMARY

According to an example, an electronic control device controls current flowing through a wire harness. The electronic control device may include: a main element that controls the current flowing through the wire harness; a sense element through which a current corresponding to the current flowing through the main element flows; a detection resistor that is connected to the sense element and generates a sense voltage corresponding to the current flowing through the sense element; a charge/discharge circuit that charges and discharges a charge/discharge capacitor based on the sense voltage; a forced discharge circuit that forcibly switches the charge/discharge circuit to a discharge state when a charging state by the charge/discharge circuit continues after exceeding an upper limit; an accumulation circuit that accumulates a multiplication signal acquired according to a voltage of the charge/discharge capacitor when discharging; a subtraction circuit that subtracts a subtraction value corresponding to a heat radiation characteristic of the wire harness from an accumulation result of the accumulation circuit; and a control circuit that controls an on/off state of the main element, and cuts off the current flowing through the wire harness when a value subtracted by the subtraction circuit exceeds an accumulation threshold corresponding to a heat generation characteristic of the wire harness. When the forced discharge circuit switches to the discharge state, the forced discharge circuit causes the accumulation circuit to accumulate an acceleration value for cut-off instead of the multiplication signal.

### BRIEF DESCRIPTION OF THE DRAWINGS

The above and other objects, features and advantages of the present disclosure will become more apparent from the following detailed description made with reference to the accompanying drawings. In the drawing:

FIG. 1 is a diagram showing the configuration of the electronic control device in the first embodiment;

FIG. 2 is a flowchart that mainly shows the processing content by the charge/discharge control unit;

FIG. 3 is a timing chart of operation;

FIG. 4 is a diagram illustrating the relationship between the accumulation value TINT, the multiplication result ADD, and the subtraction value CSUB;

FIG. 5 is a diagram showing the change in the accumulation value TINT over time;

FIGS. 6A and 6B are diagram illustrating the relationship between the range of current to be detected and the fume characteristics of the wire harness;

FIG. 7 is a diagram showing the configuration of the electronic control device in the second embodiment;

FIG. 8 is a flowchart that mainly shows the processing content by the charge/discharge control unit;

FIGS. 9A and 9B are diagrams showing the input/output characteristics depending on whether or not the gain of the amplifier gain is switched;

FIG. 10 is a timing chart of the operation;

FIG. 11 is a timing chart of the operation according to the third embodiment;

FIG. 12 is a flowchart that mainly shows the processing content by the charge/discharge control unit;

FIG. 13 is a timing chart of the operation according to the fourth embodiment;

FIG. 14 is a timing chart of the operation according to the conceivable technique; and

FIGS. 15A and 15B are diagrams showing the protection characteristics and cut-off characteristics within the detection current range of the wire harness.

### DETAILED DESCRIPTION

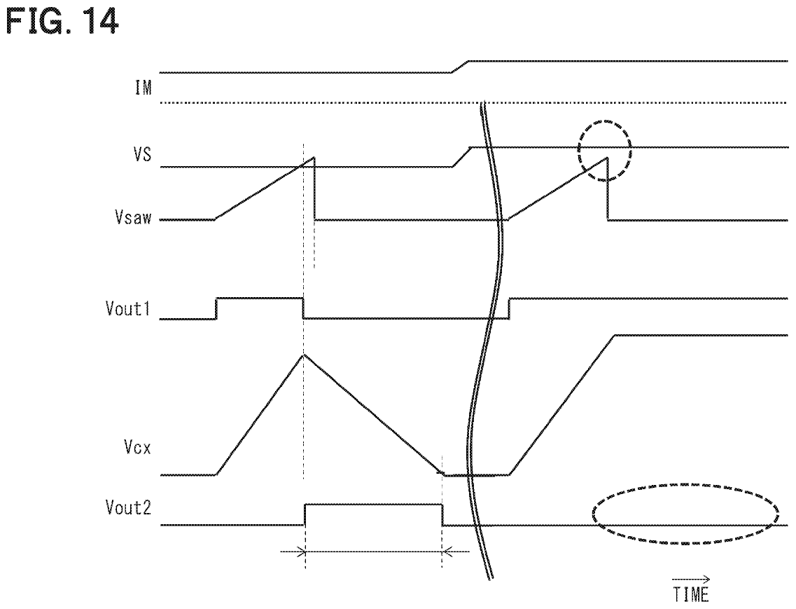

However, in the configuration of Patent Literature 1, as shown in FIG. 14, if the voltage VS corresponding to the detection current IM exceeds the input range defined by the output signal Vsaw of the DAC, the charging of the capacitor indicated by the signal Vcx continues and does not switch to discharging. As a result, a pulse width signal Vout2 corresponding to the discharge time cannot be generated, and the multiplication characteristics cannot be acquired.

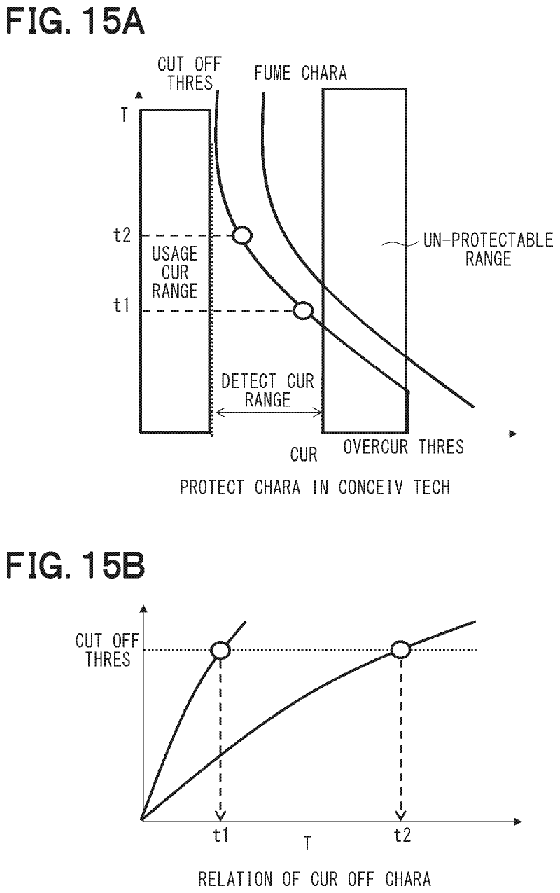

As shown in FIGS. 15A and 15B, in practical application, a wire harness is selected whose fume characteristics are greater than or equal to the current range to be used, and the cutoff threshold of the e-Fuse is set within a range that is greater than or equal to the usage current range and less than or equal to the fume characteristics. The cutoff threshold set in the e-Fuse is constant, but when the current is large, the time t1 to reach the cutoff threshold is short, and when the current is small, the time t2 to reach the cutoff threshold is longer.

Furthermore, the multiplication circuit described in Patent Literature 1 does not include a means for detecting when the input current exceeds the detection range, as shown in the area enclosed by the dashed line in FIG. 14. Therefore, as shown in FIGS. 15A and 15B, there was a difficulty in that the range equal to or less than the overcurrent threshold for protecting the IPD itself and equal to or greater than the current detection range in the e-Fuse were disposed in the dead zone or un-protectable area where the wire harness could not be protected.

This disclosure has been made in view of the above circumstances, and its purpose is to provide an electronic control device that can protect a wire harness even when the current exceeds the detection range.

According to the electronic control device described in feature 1, the main element controls the current flowing through the wire harness, and a current corresponding to the current flowing through the main element flows through the sense element. The detection resistor generates a sense voltage corresponding to the current flowing through the sense element. The charge/discharge circuit charges and discharges the charge/discharge capacitor based on the sense voltage. The forced discharge circuit forcibly switches the charge/discharge circuit to a discharge state if the charging state by the charge/discharge circuit continues after exceeding the upper limit.

The accumulation circuit accumulates the multiplication signal acquired according to the discharge voltage in the charge/discharge capacitor, and the subtraction circuit subtracts a subtraction value according to the heat radiation characteristics of the wire harness from the accumulation result of the accumulation circuit. The control circuit controls the on/off state of the main element, and when the value subtracted by the subtraction circuit exceeds an accumulation threshold corresponding to the heat generation characteristics of the wire harness, the control circuit cuts off the current flowing through the wire harness. When the forced discharge circuit switches to the discharge state, the forced discharge circuit causes the accumulation circuit to accumulate the acceleration value for cut-off instead of the multiplication signal.

The charging time of a charge/discharge capacitor is determined by the magnitude of the sense voltage generated by the detection resistor, and the longer the charging time, the longer the discharge time. Therefore, when the charging state by the charge/discharge circuit continues after exceeding the upper limit, it can be determined that the value of the current flowing through the sense element has become somewhat large, and that it is in an over-range state in which exceeding the current range for the detection target.

Therefore, the forced discharge circuit causes the accumulation circuit to accumulate the acceleration value for the cut-off instead of the multiplication signal, so that the rising rate of the accumulation value is increased, and the accumulation value exceeds the accumulation threshold more quickly, and the forced discharge circuit causes the control circuit to turn off the main element and cuts off the current flowing through the wire harness. This ensures that the wire harness is protected even if the detection current goes into an over-range state, also known as an overcurrent state.

According to the electronic control device described in feature 2, the forced discharge circuit stops subtraction by the subtraction circuit when it causes the accumulation circuit to accumulate the acceleration value for the cut-off. As a result, the current can be rapidly cut off.

According to the electronic control device described in feature 3, the comparison value setting unit gradually increases the comparison value over time. The charge/discharge switching unit switches the charging state by the charge/discharge circuit to the discharge state when the comparison value exceeds the sense voltage. As a result, the charge/discharge circuit enters a charging state when the sense voltage exceeds the comparison value, and switches to a discharging state when the comparison value exceeds the sense voltage. If the length of the period of time in which the sense voltage exceeds the comparison value is a certain length of period of time, the charging state by the charge/discharge circuit has continued after exceeding the upper limit, and the forced discharge circuit will forcibly switch the forced discharge circuit causes the charge/discharge circuit to be switched to the discharge state.

### First Embodiment

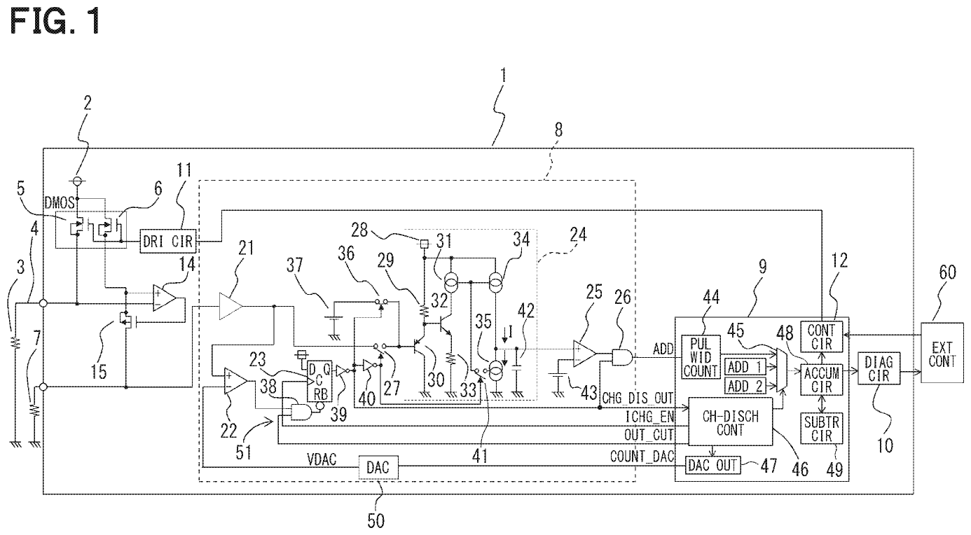

As shown in FIG. 1, the electronic control device 1 of this embodiment is arranged between the power supply 2 and the load 3 via a wire harness 4 and is connected to the external control unit 60. The electronic control unit 1 includes a main element 5, a sense element 6, a detection resistor 7, a multiplication circuit 8, a control logic 9, a diagnostic circuit 10, and the like. Furthermore, the electronic control unit 1 is packaged together with all of the above-mentioned components so that it constitutes an intelligent power device (IPD).

In this embodiment, the main element 5 and the sense element 6 include n-channel type MOSFETs (Metal Oxide Semiconductors), alternatively, they may also be IGBTs (Insulated Gate Bipolar Transistors) or the like. The gates of the main element 5 and the sense element 6 are connected to a drive circuit 11 that applies a predetermined gate voltage. The main element 5 and the sense element 6 can be switched between an on state, where current flows according to the gate voltage to be applied, and an off state, where current is cut off according to the gate voltage to be applied. The drive circuit 11 is connected to the control circuit 12, which will be described later, and controls the on and off states of the main element 5 and the sense element 6 based on drive instructions from the control circuit 12.

Furthermore, the main element 5 and the sense element 6 are formed to have a predetermined area ratio, and the current flowing through the main element 5 and the sense element 6, respectively, is a value corresponding to the area ratio. In this embodiment, the main element 5 and the sense element 6 are formed on a common semiconductor substrate, although details are not shown. The detection resistor 7, the multiplication circuit 8, the control logic 9, the diagnostic circuit 10, and the like are formed on a semiconductor substrate separate from the semiconductor substrate on which the main element 5 and sense element 6 are formed. Furthermore, the electronic control device 1 is packaged by integrating a semiconductor substrate on which the main element 5 and sense element 6 are formed with a semiconductor substrate on which the detection resistor 7 and the like are formed, using a sealing member.

The drains of the main element 5 and the sense element 6 are connected to the power supply 2. Furthermore, the source of the main element 5 is connected to the load 3 via the wire harness 4, and is also connected to the inversion input terminal of the current detection amplifier 14, which will be described later. The source of the sense element 6 is connected to the non-inversion input terminal of the current detection amplifier 14.

The detection resistor 7 is connected to the sense element 6 via the current detection amplifier 14 and the P-channel MOSFET 15. The source of the FET 15 is connected to the source of the sense element 6 and the non-inversion input terminal of the current detection amplifier 14, and the drain is connected to the detection resistor 7. The gate of FET 15 is connected to the output terminal of the current detection amplifier 14.

The multiplication circuit 8 includes an amplifier 21, a comparator 22, a D latch 23, a charge/discharge circuit 24, a comparator 25, and an AND gate 26, and the like. A detection resistor 7 is connected to the input terminal of the amplifier 21. The detection resistor 7 generates a sense voltage corresponding to the value of the current being supplied. The sense voltage is amplified by the amplifier 21 at a predetermined amplification factor and supplied to the non-inversion input terminal of the comparator 22 and to the charge/discharge circuit 24 via the switch 27.

The charging/discharging circuit 24 includes a series circuit of a resistor 29 and a PNP transistor 30, a series circuit of a current source 31, an NPN transistor 32 and a resistor 33, and series circuits of current sources 34 and 35, all of which are connected between the power supply 28 and the ground. In addition to the switch 27, a reference power supply 37 is connected to the base of transistor 30 via the switch 36. The on/off state of switches 27 and 36 is controlled by the D latch 23.

The input terminal D of the D latch 23 is pulled up to the power supply 28. The clock terminal C of the D latch 23 receives the trigger signal ICHG_EN from the control logic 9. The output terminal of the AND gate 38 is connected to the negative logic reset terminal RB of the D latch 23. One input terminal of the AND gate 38 is connected to the output terminal of the comparator 22, and the other input terminal is connected to the signal OUT_CUT from the control logic 9.

NOT gates 39 and 40 are connected in series to the output terminal Q of the latch 23. In addition to the switch 27, the on/off state of switch 41, which constitutes the charge/discharge circuit 24, is controlled by the output signal of the NOT gate 40, and the on/off state of the switch 36 is controlled by the output signal of the NOT gate 39. In other words, the on/off states of switches 27 and 41 and the on/off state of switch 36 are controlled by signals that are in opposite phases to each other. Furthermore, the output signal of the NOT gate 39 is input to the control logic 9 as the signal CHG_DIS_OUT, and is also supplied to one of the input terminals of the AND gate 26. The comparator 22, D latch 23, AND gate 38, NOT gates 39 and 40 constitute the charge/discharge switching unit 51.

The common connection point of current sources 34 and 35 is connected to ground via the charge/discharge capacitor 42 and is also connected to the non-inversion input terminal of the comparator 25. A reference power supply 43 is supplied to the inversion input terminal of the comparator 25. The output terminal of the comparator 25 is connected to the other input terminal of the AND gate 26.

The control logic 9 includes a pulse width counter 44, a multiplexer 45, a charge/discharge control unit 46, a DAC output unit 47, an accumulation circuit 48, and a subtraction circuit 49, and the like. The pulse width counter 44 counts the length of time during which the output signal ADD of the AND gate 26 is at a high level, and inputs the count result to the multiplexer 45. The multiplexer 45 also has “addition value 1” and “addition value 2” as inputs, but in this embodiment only “addition value 2” is used. Furthermore, in the below description, “additional values 1 and 2” may be referred to as “acceleration values 1 and 2”. The input selection of the multiplexer 45 is controlled by the charge/discharge control unit 46.

The output signal of the multiplexer 45 is input to the accumulation circuit 48. The accumulating circuit 48 is connected to the subtracting circuit 49, as well as the aforementioned diagnostic circuit 10 and control circuit 12. The diagnostic signal output by the diagnostic circuit 10 is input to the external control unit 60. The output signal from the external control unit 60 is input to the control circuit 12. The charge/discharge control unit 46 controls the DAC output unit 47 to input digital values to the DAC (digital-to-analog converter) 50. The DAC 50 generates an analog voltage signal VDAC corresponding to the input digital value and outputs it to the inversion input terminal of the comparator 22. The charge/discharge control unit 46 corresponds to a forced discharge circuit. Furthermore, the charge/discharge control unit 46, the DAC output unit 47, and the DAC 50 correspond to the comparison value setting unit.

The external control unit 60 includes a microcomputer and the like which has a CPU (Central Processing Unit) and a memory unit such as ROM (Read Only Memory), RAM (Random Access Memory), and non-volatile RAM. The CPU of the external control unit 60 reads out a program from the ROM or the non-volatile RAM to execute the program so that various control operations are realized. The ROM or non-volatile RAM preliminarily stores various types of data to be used during program execution, such as initial values, lookup tables, maps, and so on.

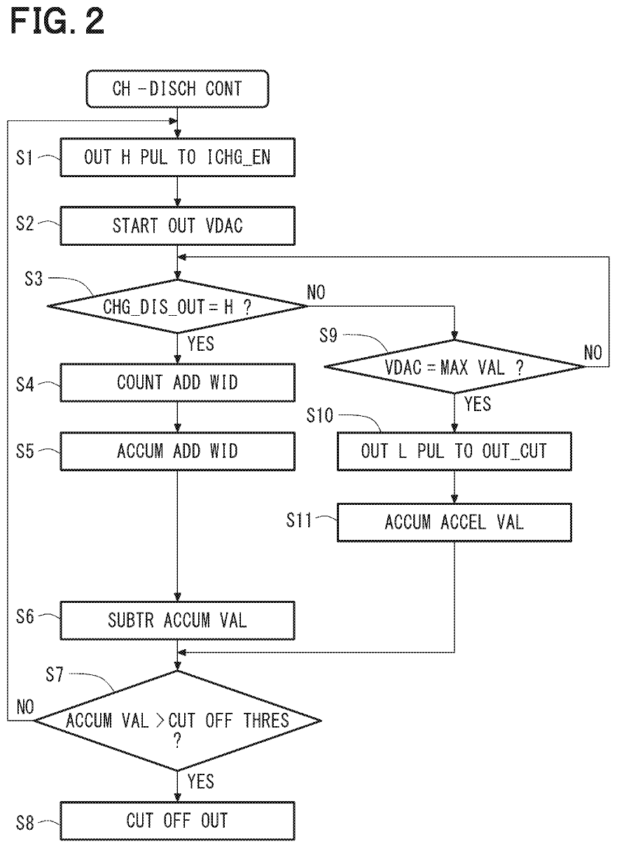

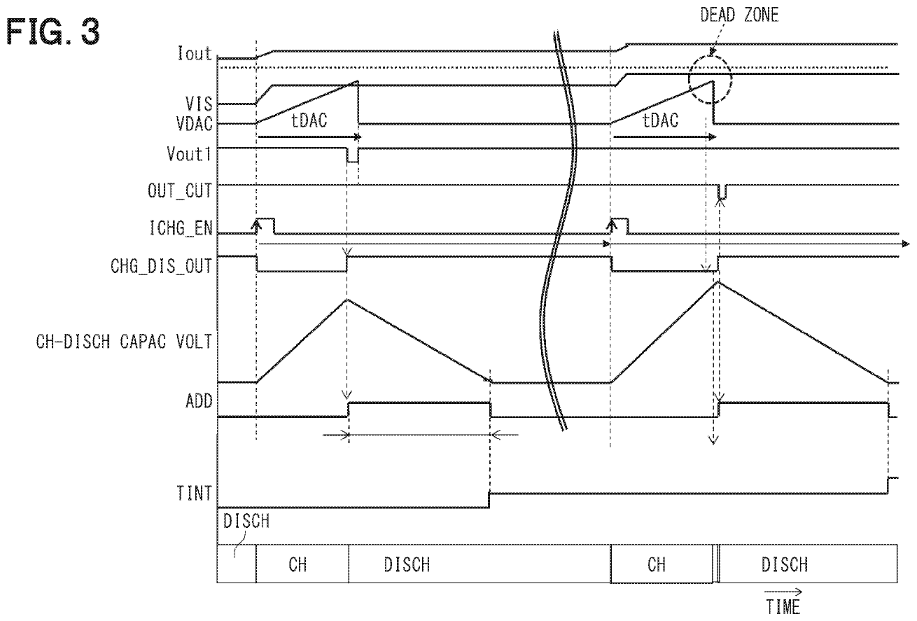

Next, the operation of the present embodiment will be described. As shown in FIG. 2, when the charge/discharge control unit 46 outputs a high-level pulse as the signal ICHG_EN (at step S1), the charge/discharge control unit 46 controls the DAC output unit 47 to start outputting the voltage signal VDAC (at step S2). This results in the output of a sawtooth wave voltage tDAC, as shown in FIG. 3. Next, it is determined whether the signal CHG_DIS_OUT output by the D latch 23 via the NOT gate 39 is high level or not (at step S3). If the signal CHG_DIS_OUT is at a low level (“NO”), it is determined whether the voltage signal VDAC has reached its maximum amplitude (at step S9). If it has not reached its maximum amplitude (“NO”), the process returns to step S3. During the period when the signal CHG_DIS_OUT is at a low level, the charge/discharge capacitor 42 is being charged.

When the signal CHG_DIS_OUT goes high (“YES” at S3), the pulse width counter 44 starts counting the pulse width of the signal ADD output by the AND gate 26 (at step S4). At this time, the charge/discharge capacitor 42 switches to the discharge state. When the ADD signal goes low, the counting operation ends and the pulse width value is accumulated by the accumulation circuit 48 (at step S5). At this time, the charge/discharge control unit 46 sets the input selection of the multiplexer 45 to the pulse width counter 44 side. Then, a value corresponding to the heat radiation characteristics of the wire harness 4 is subtracted from the accumulation value by the subtraction circuit 49 (at S6). TINT shown in FIG. 3 is the accumulation value in the accumulation circuit 48.

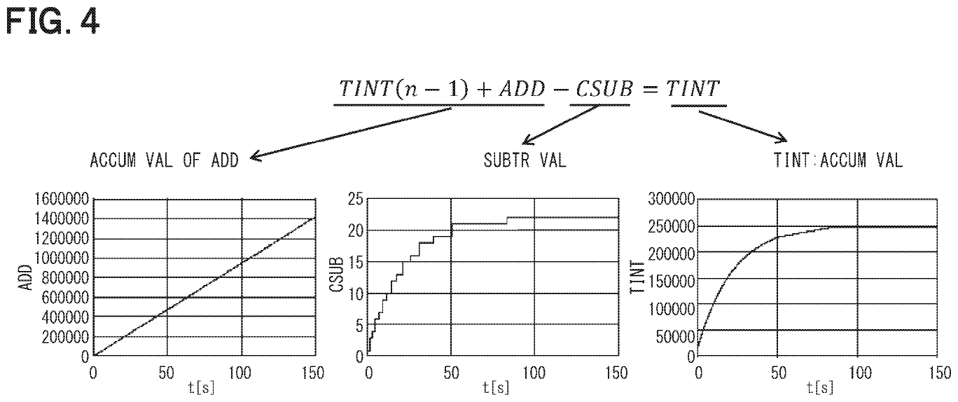

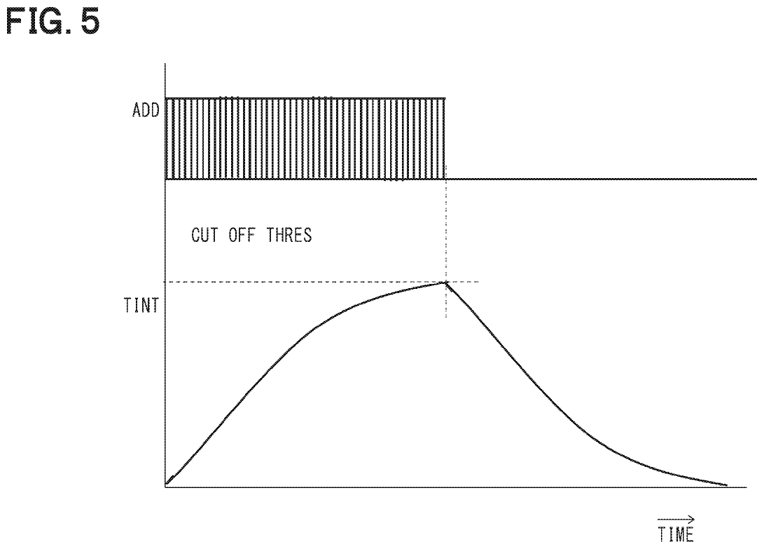

Here, as shown in FIG. 4, the accumulation value TINT(n) is acquired by adding the pulse width count value ADD to the previous accumulation value TINT(n-1) and subtracting the subtraction value CSUB. The subtraction value CSUB is determined by (1−e^{-Δt/π}) and is a heat radiation characteristic that can be acquired from the thermal time constant of the wire harness 4. FIG. 5 shows the case where the accumulation value TINT reaches the cutoff threshold while the input voltage is within the detection range. In FIG. 4, ADD indicates a multiplication result, CSUB indicates a thermal radiation characteristic of wire acquired from thermal time constant of wire and defined by an expression of (1−e^{-Δt/π}), and TINT indicates an accumulation value.

If the accumulation value does not exceed the cutoff threshold for e-Fuse operation (“NO” at S7), the process returns to step S1. When the accumulation value exceeds the cutoff threshold (“YES” at S7), the control circuit 12 turns off the main element 5 and the sense element 6 via the drive circuit 11, thereby cutting off the power supply to the load 3 (at S8). The cutoff threshold corresponds to the accumulation threshold.

In step S9, when the voltage signal VDAC reaches its maximum amplitude (“YES” at S9), the charge/discharge control unit 46, which is a forced discharge circuit, outputs a low-level pulse as the signal OUT_CUT (at S10). As a result, when entering the dead zone shown and surrounded by the dashed line in FIG. 3, the charge/discharge capacitor 42 is forced to switch to the discharge state. Then, the input selection of the multiplexer 45 is used as the acceleration value (2) and accumulated by the accumulation circuit 48 (at S11). Then, the process proceeds to S7. The time it takes for the voltage signal VDAC to reach its maximum amplitude corresponds to the upper limit. Furthermore, the acceleration value (2) corresponds to the acceleration value for cutoff.

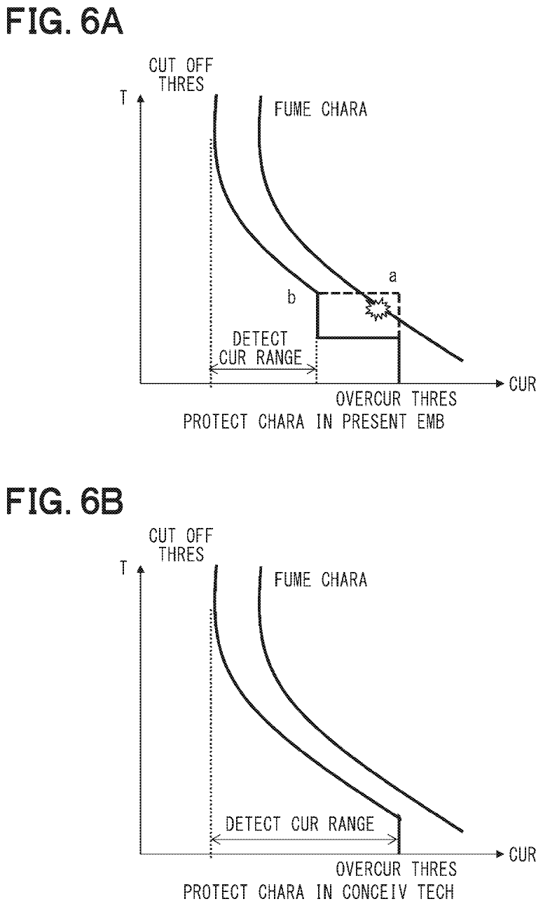

Here, the reason for accumulating the acceleration values will be described. When the upper limit of the pulse width range of the signal ADD is added in the over-range state, the result becomes a as shown in FIGS. 6A and 6B. Since the cutoff time remains constant for currents equal to or larger than the detection range, the current exceeds the fume characteristics of wire harness 4 when the current becomes large. This shows the dead zone. Furthermore, the fume characteristics of wire harnesses are described in detail in paragraphs [0021] to [0024] of JP 2023-18957-A. All of the contents of JP 2023-18957-A are incorporated herein by reference.

Therefore, if the current value is equal to or larger than the detection range, the current is cut off more quickly by accumulating the acceleration value instead of the pulse width, as shown in b of the drawing. The acceleration value is set so that the cutoff threshold in the dead zone does not exceed the fume characteristics of the wire harness 4. If the calculation in the e-Fuse processing is executed, for example, once every 4 ms, and it is necessary to cut off within 100 ms, the acceleration value is set to reach the cutoff threshold after 25 times of the accumulation calculations.

According to the present embodiment, the main element 5 controls the current flowing through the wire harness 4, and a current corresponding to the current flowing through the main element 5 flows through the sense element 6. The detection resistor 7 generates a sense voltage corresponding to the current flowing through the sense element 6. The charge/discharge circuit 24 charges and discharges the charge/discharge capacitor 42 based on the sense voltage. The charge discharge control circuit 46 forcibly switches the charge/discharge circuit 24 to a discharge state if the charging state by the charge/discharge circuit 24 continues after exceeding the upper limit.

The accumulation circuit 48 accumulates the multiplication signal acquired according to the discharge voltage in the charge/discharge capacitor 42, and the subtraction circuit 49 subtracts a subtraction value according to the heat radiation characteristics of the wire harness 4 from the accumulation result of the accumulation circuit 48. The control circuit 12 controls the on/off state of the main element 5, and when the value subtracted by the subtraction circuit 49 exceeds an accumulation threshold corresponding to the heat generation characteristics of the wire harness 4, the control circuit 12 cuts off the current flowing through the wire harness 4. When the charge discharge control circuit 46 switches to the discharge state, the charge discharge control circuit 46 causes the accumulation circuit 48 to accumulate the acceleration value for cut-off instead of the multiplication signal.

More specifically, the charge/discharge control unit 46 gradually increases the voltage signal VDAC, which is a comparison value, over time via the DAC output unit 47 and the DAC 50. The charge/discharge switching unit 51 switches the charging state by the charge/discharge circuit 24 to the discharge state when the comparison value exceeds the sense voltage. The charging time of a charge/discharge capacitor 42 is determined by the magnitude of the sense voltage generated by the detection resistor 7, and the longer the charging time, the longer the discharge time. Therefore, when the charging state by the charge/discharge circuit 24 continues after exceeding the upper limit, it can be determined that the value of the current flowing through the sense element 6 has become somewhat large, and that it is in an over-range state in which exceeding the current range for the detection target.

Therefore, the charge discharge control circuit 46 causes the accumulation circuit 48 to accumulate the acceleration value for the cut-off instead of the multiplication signal, so that the rising rate of the accumulation value is increased, and the accumulation value exceeds the accumulation threshold more quickly, and the charge discharge control circuit 46 causes the control circuit 12 to turn off the main element 5 and cuts off the current flowing through the wire harness 4. This ensures that the wire harness 4 is protected even if the detection current goes into an over-range state, also known as an overcurrent state. Furthermore, since the subtraction by the subtraction circuit 49 is stopped at that time, the current can be cut off earlier.

### Second Embodiment

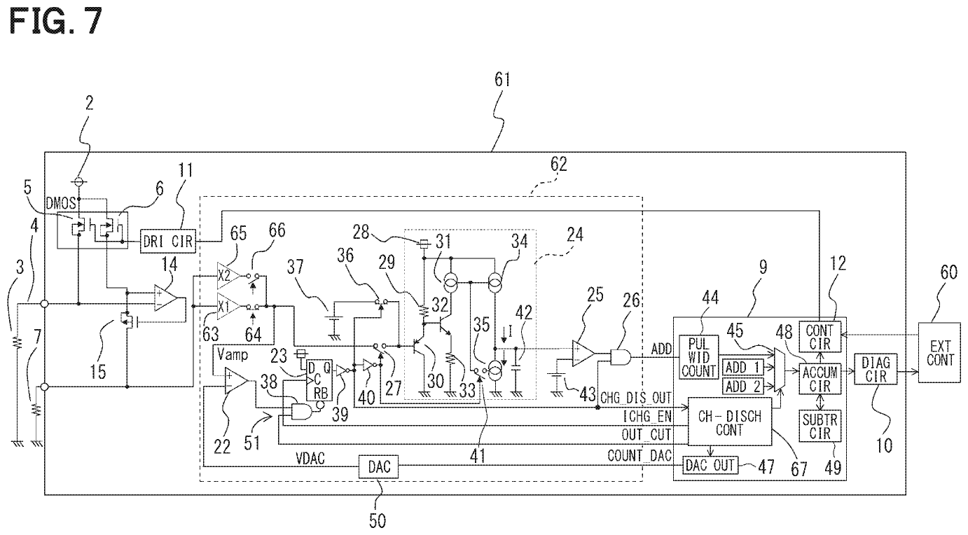

Hereinafter, the identical parts as those in the first embodiment will be designated by the same reference numerals for simplification of the description. Only differences from the first embodiment will be described below. As shown in FIG. 7, the electronic control device 61 of the second embodiment includes a multiplication circuit 62 instead of the multiplication circuit 8. In the multiplication circuit 62, instead of the amplifier 2, a series circuit of amplifier 63 and switch 64, and a series circuit of amplifier 65 and switch 66 are connected in parallel. The amplification factors, that is gains, of amplifiers 63 and 65 are set to be 1× and 2×, respectively. The on/off operation of the switches 64 and 66 is executed by the charge/discharge control unit 67, instead of the charge/discharge control unit 46. In the second embodiment, the two amplifiers 63 and 65 are selected by switching the switches 64 and 66 to be on and off, and are therefore considered to be “amplifiers whose amplification factor can be changed”.

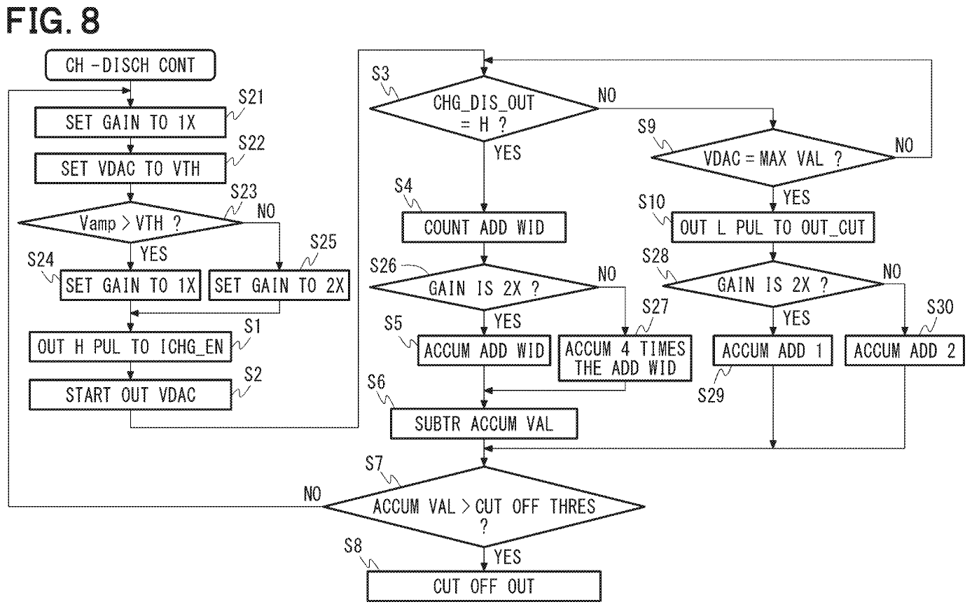

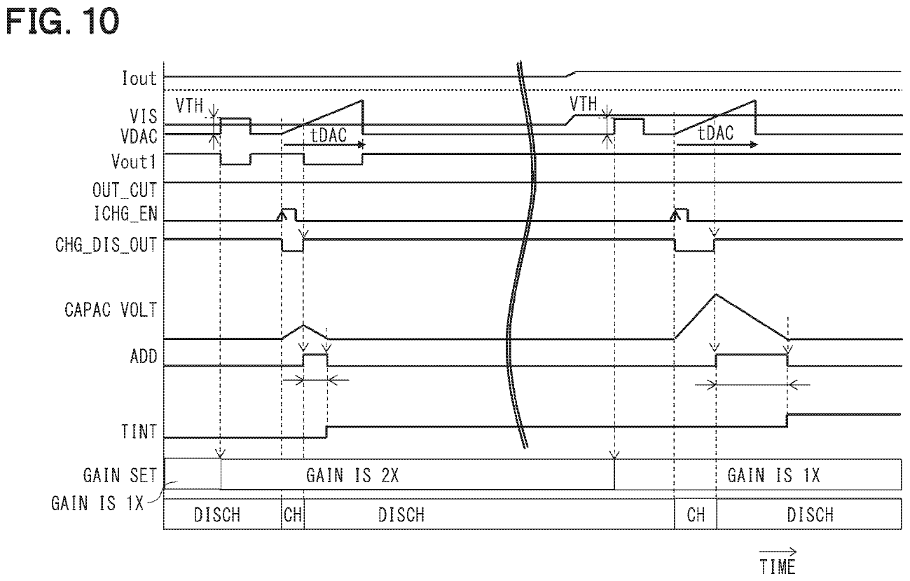

Operation of the second embodiment will be described next. In the following, the output signal of amplifier 63 or 65 will be referred to as Vamp. As shown in FIG. 8, the charge/discharge control unit 67 first turns on the switch 64 and off the switch 66 to select the amplifier 63 side with a gain of 1× (at S21). Then, the DAC output unit 47 is controlled to set the level of the voltage signal VDAC to the selection threshold VTH shown in FIG. 10 (at S22).

In this case, the comparator 22 compares the output signal Vamp of the amplifier 63 with the level of the voltage signal VDAC, i.e., the selection threshold VTH (at S23). If the expression of “Vamp>VTH” is established (“YES” at S23), the charge/discharge control unit 67 maintains the on/off state of switches 64 and 66 and continues to select the amplifier 63 side with a gain of 1× (at S24). On the other hand, if the expression of “Vamp≤Vth” is established (“no” at S23), the switch 64 is turned off and the switch 66 is turned on to select the amplifier 65 side with a gain of 2× (at S25). Note that the details of the logic for switching between amplifiers 63 and 65 are omitted in FIG. 7.

Next, after executing steps S1 to S4, it is determined whether the gain setting is 2× or not (at S26). If the gain setting is 2× (“YES” at S26), step S5 is executed. If the gain setting is 1× (“NO” at S26), four times the pulse width of the ADD signal is accumulated to compensate for the difference from the case of the gain setting of 2x (at S27). Then, steps S6 to S10 are executed.

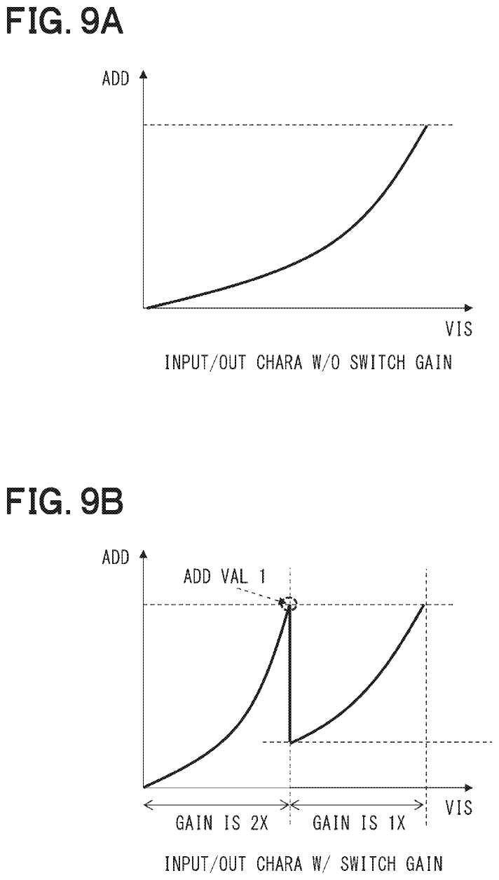

If the range is over and step S10 is executed, the same determination as in step S26 is made (at S28). If the gain is set to 2× (“YES” at S28), the charge/discharge control unit 67 controls the multiplexer 45 to accumulate the acceleration value 1 as shown in FIGS. 9A and 9B (at S29). Here, the acceleration value 1 corresponds to the upper limit of the input range for the sense voltage. On the other hand, if the gain is set to 1× (“NO” at S28), the acceleration value 2 is accumulated (at S30). These features allow for early cutoff of the current in case of an over-range by accumulating the acceleration values corresponding to the gain setting.

### Third Embodiment

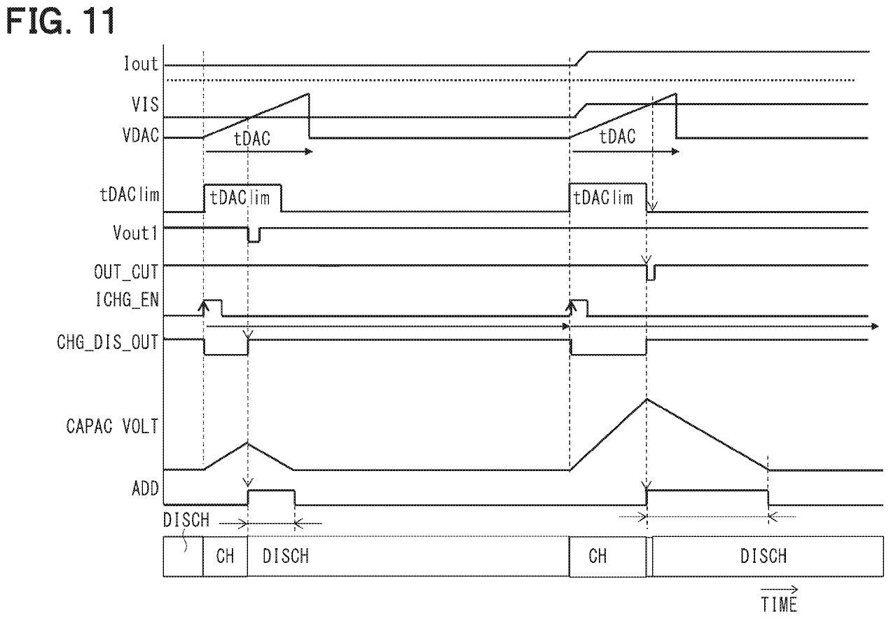

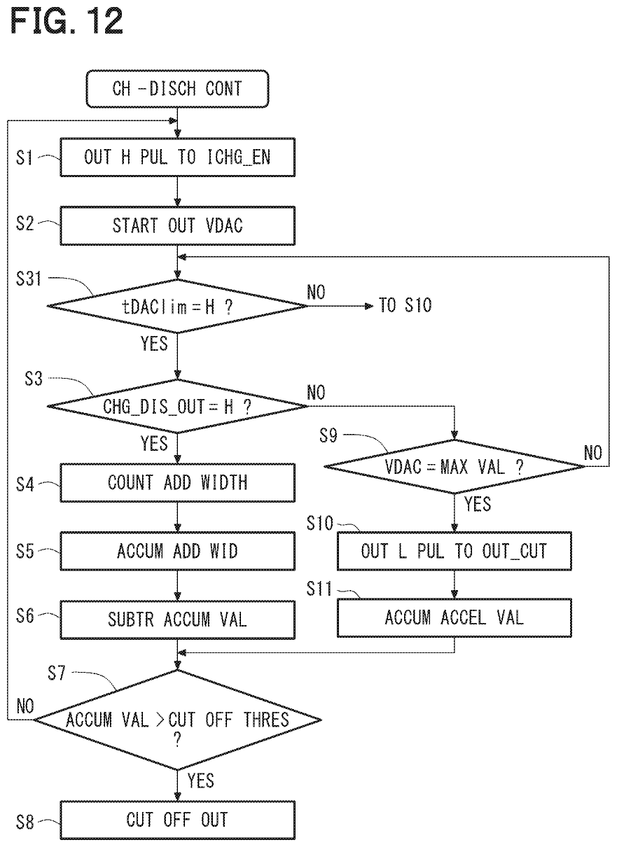

In the third embodiment shown in FIGS. 11 and 12, for example, the charge/discharge control unit 46 of the first embodiment switches to forced discharge by a time filter function. As shown in FIG. 12, when the charge/discharge control unit 46 starts outputting the voltage signal VDAC (at S2), it starts counting a certain period of time tDAClim. The internal signal tDAClim is at a high level during the counting period and changes to a low level after a certain period of time tDAClim has elapsed. If the internal signal tDAClim is at a high level (“YES” at S31), steps S3 to S11 are executed. When the internal signal tDAClim changes to a low level (“NO” at S31), the process proceeds to step S10 and switches to discharge forcibly.

### Fourth Embodiment

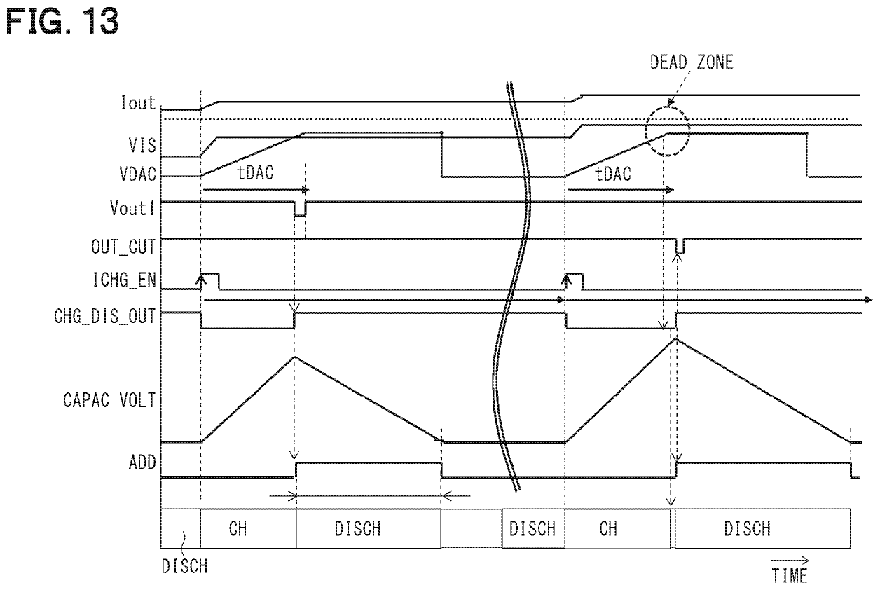

In the fourth embodiment shown in FIG. 13, the waveform of the voltage signal VDAC is not a sawtooth wave, but rather a waveform that maintains a constant voltage once it reaches a certain value.

### Other Embodiments

Step S6 may be executed if the acceleration values are accumulated. In the second embodiment, the amplification factor may be changed for a single amplifier. Furthermore, in the second embodiment, the gain setting may be set to three or more levels. Similar to the conceivable technique, the subtraction rate used in the subtraction circuit 49 may be adjusted by inputting a subtraction rate adjustment signal to the external control unit 60 via an external communication circuit (not shown) so that it matches the heat radiation characteristics of the wire harness 4 to be used.

Although the present disclosure has been described according to the embodiments, it is understood that the present disclosure is not limited to the above-described embodiments or structures. The present disclosure includes various modifications or deformations within an equivalent range. Furthermore, various combination and formation, and other combination and formation including one, more than one or less than one element may be made within the spirit and scope of the present disclosure.

What is claimed is:

1. An electronic control device that controls current flowing through a wire harness, the electronic control device comprising:
a main element that controls the current flowing through the wire harness;
a sense element through which a current corresponding to the current flowing through the main element flows;
a detection resistor that is connected to the sense element and generates a sense voltage corresponding to the current flowing through the sense element;
a charge/discharge circuit that charges and discharges a charge/discharge capacitor based on the sense voltage;
a forced discharge circuit that forcibly switches the charge/discharge circuit to a discharge state when a charging state by the charge/discharge circuit continues after exceeding an upper limit;
an accumulation circuit that accumulates a multiplication signal acquired according to a voltage of the charge/discharge capacitor when discharging;
a subtraction circuit that subtracts a subtraction value corresponding to a heat radiation characteristic of the wire harness from an accumulation result of the accumulation circuit; and
a control circuit that controls an on/off state of the main element, and cuts off the current flowing through the wire harness when a value subtracted by the subtraction circuit exceeds an accumulation threshold corresponding to a heat generation characteristic of the wire harness, wherein:
when the forced discharge circuit switches to the discharge state, the forced discharge circuit causes the accumulation circuit to accumulate an acceleration value for cut-off instead of the multiplication signal.

2. The electronic control device according to claim 1, wherein:
the forced discharge circuit stops subtraction by the subtraction circuit when the forced discharge circuit causes the accumulation circuit to accumulate the acceleration value for the cut-off.

3. The electronic control device according to claim 1, further comprising:
a comparison value setting unit that gradually increases a comparison value over time; and
a charge/discharge switching unit that switches a charge state of the charge/discharge circuit to a discharge state when the comparison value exceeds the sense voltage.

4. The electronic control device according to claim 3, further comprising:
an amplifier that amplifies the sense voltage and an amplification factor can be changed, wherein:
the forced discharge circuit sets the amplification factor according to a level of the sense voltage;
when the amplification factor is set to a minimum, the forced discharge circuit causes the control circuit to accumulate the acceleration value for the cutoff; and
when the amplification factor is not set to the minimum, the forced discharge circuit causes the control circuit to accumulate an upper limit of an input range of the sense voltage.

5. The electronic control device according to claim 4, wherein:
the comparison value setting unit outputs a selection threshold for selecting the amplifier for a certain period of time before gradually increasing the comparison value over time; and
the forced discharge circuit compares the sense voltage with the selection threshold to select the amplifier.
